(19) United States
(12) Patent Application Publication
(10) Pub. No.: US 2010/0092799 A1
(43) Pub. Date: Apr. 15, 2010

(54) METAL COATING PROCESS AND PRODUCT

(75) Inventors: Surry D. McFaul, Sarasota, FL (US); Frederick G. Grawunde, Sarasota, FL (US)

Correspondence Address: SHUMAKER LOOP & KENDRICK, 101 E. KENNEDY, SUITE 2800, TAMPA, FL, 33672-0609, US

(73) Assignee: Sun Hydraulics Corporation, Sarasota, FL (US)

(21) Appl. No.: 12/558,069

(22) Filed: Sep. 11, 2009

Related U.S. Application Data
(63) Continuation of application No. 11/509,966, filed on Aug. 25, 2006.

(51) Int. Cl. B32B 15/01; C23C 14/35

(52) U.S. Cl. 428/659; 204/192.12; 204/192.15

(57) ABSTRACT

A process for coating a metal part with a magnetron-sputtered material to provide corrosion protection is disclosed. The process results in a part having a uniform thin coating. Coating materials include corrosion resistant zinc with various options for appearances and levels of corrosion protection.

This application is a continuation of U.S. Non-Provisional application Ser. No. 11/509,966, filed on Aug. 25, 2006, which is hereby incorporated by reference.

### BACKGROUND

1. Technical Field

This invention relates to coating metals.

2. Background Information

Numerous uses of metal components or parts require coating or plating a metal substrate with a separate material to provide an end product with a desired characteristic. One such characteristic is corrosion resistance. Galvanizing or chrome electroplating, for example, renders metal parts significantly more corrosion resistant than the substrate material.

Conventional forms of plating, however, have numerous known drawbacks. In electroplating, for example, a substrate or part is placed into a series electrically charged baths and dips. The baths and dips require using chemicals such as solvents, volatile organics, and/or other hazardous materials. For example, one chemical commonly used in electroplating is cyanide. Such chemicals can be harmful to workers that are exposed to them, harmful to the environment, and expensive to dispose of, among other things. Moreover, since electroplating requires good ventilation, it is often performed in non-heated and non-cooled buildings, thus creating difficult working conditions.

Additionally, conventional forms of electroplating frequently result in non-uniform thickness of the plating. In actuality, the thickness in electroplating can vary by as much as five times the specified coating thickness due to low and high current density zones on a single part. Parts with too much plating can result in excessively thick threads. Excessively thick threads, in turn, can result in parts that do not fit together properly or obstruct the mechanics of the part, especially in applications involving very tight tolerances. On the other hand, when the plating is too thin or spotty, then the desired corrosion resistance is not achieved. In either case, the plated part is unusable and must be either re-plated (if possible) or otherwise recycled (if possible).

### BRIEF SUMMARY

The foregoing problems are solved and a technical advance is achieved in an illustrative process for coating a metal part, a part created using that process, or a corrosion resistant cylindrical valve.

According to one aspect of the present invention, the process provides an environmentally sound alternative to conventional electroplating. That is, according to one aspect of the present invention, the process utilizes environmentally friendly materials, thereby sharply reducing—or entirely eliminating—costs associated with using hazardous materials. Since non-hazardous materials are used, the process can be performed in climate-controlled buildings. Moreover, according to one aspect of the present invention, this process also provides coating that is thinner and significantly more uniform in thickness than electroplated coatings, while having equal or improved corrosion resistance relative to electroplated coatings. In one embodiment of the present invention, a thin, uniform, protective coating is provided as a solution to the problem of protecting metal parts from corrosion without affecting critical dimensions of the metal parts.

In another aspect of the present invention, the process includes a number of steps for coating a metal part. In particular, the process involves cleaning the metal part to remove oil residues and other pollutants on the metal part. The cleaning is performed with heated water and a detergent, or, alternatively, a solvent. If the part is cleaned with water and an aqueous detergent, it is rinsed in one or more cascade baths using heated, filtered water. The metal part is then dried with an air knife and cooled to a predetermined temperature. Once cooled, the metal part is subjected to Plasma Vapor Deposition (“PVD”) or more specifically “sputtering.” The PVD process deposits one layer of corrosion resistant material on the metal part. After the PVD process, the metal part is bathed in a passivate solution and a rust inhibitor solution, then dried.

In another aspect of the present invention, a metal part is provided having a surface treated in accordance with a process for coating the metal part.

In yet another aspect of the present invention, a metal part such as a cylindrical valve body having corrosion resistance to environmental exposure is provided. The cylindrical valve includes an interior portion, as well as an exterior portion having a threaded region and a hexagonal region. The cylindrical valve body is provided with a layer of corrosion resistant material formed from a sacrificial metal such as a zinc alloy. The corrosion resistant material is provided with a uniform thickness and is isotropically disposed on the exterior portion of the cylindrical valve. This coated valve further has a number of finishes, including different colors and levels of luster.

### BRIEF DESCRIPTION OF THE DRAWINGS

FIG. 1 illustrates one embodiment of a process for coating a metal part;

FIG. 2 illustrates one embodiment a first side view of a magnetron sputtering device;

FIG. 3 illustrates a second side view of one embodiment of a magnetron sputtering device;

FIG. 4 illustrates a perspective side view of a cross section of a valve having a corrosion resistant surface;

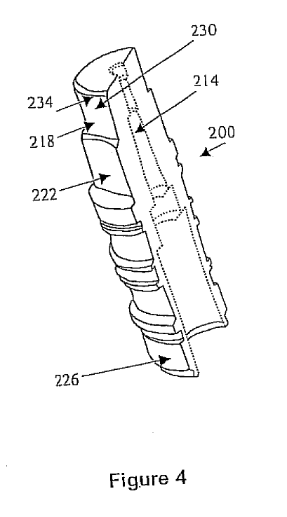

FIG. 5 illustrates a scanning electron micrograph at 5,000 times magnification of a cross section of a steel substrate conventionally plated with zinc;

FIG. 6 illustrates a scanning electron micrograph at 5,000 times magnification of a cross section of steel substrate sputter coated with zinc;

FIG. 7 illustrates a micrograph at 116 times magnification of a cross section of a steel crest of a thread conventionally plated with zinc;

FIG. 8 illustrates a micrograph at 116 times magnification of a cross section of a steel crest of a thread sputter coated with zinc;

FIG. 9 illustrates a micrograph at 575 times magnification of the upper left corner of the thread crest of FIG. 7; and

FIG. 10 illustrates a micrograph at 575 times magnification of the upper left corner of the thread crest of FIG. 8.

### DETAILED DESCRIPTION OF THE DRAWINGS AND THE PRESENTLY PREFERRED EMBODIMENTS

The invention is described with reference to the drawings in which like elements are referred to by like numerals. The relationship and functioning of the various elements of this invention are better understood by the following detailed description. However, the embodiments of this invention as described below are by way of example only, and the invention is not limited to the embodiments illustrated in the drawings. It should also be understood that the drawings are not to scale and in certain instances details have been omitted, which are not necessary for an understanding of the present invention, such as conventional details of fabrication and assembly.

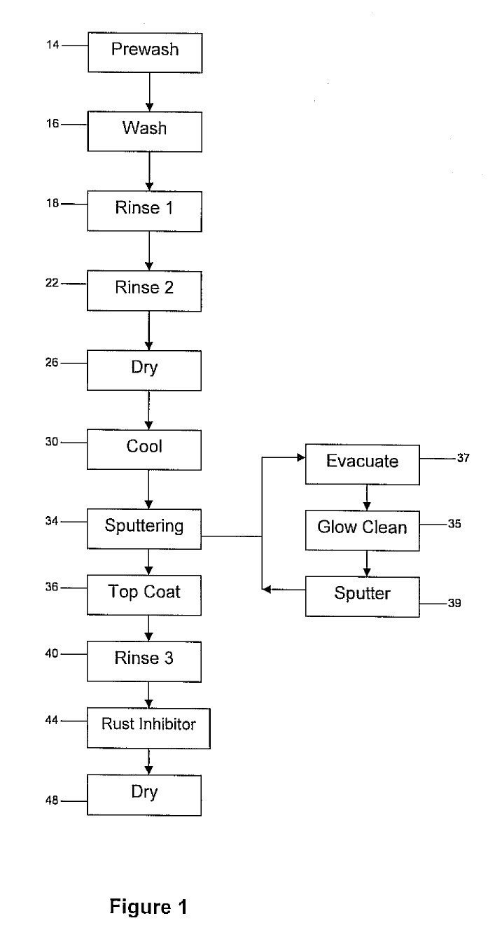

In general, FIG. 1 illustrates a method 10 of coating a metal substrate or part such as a valve with a sacrificial alloy to prevent or reduce corrosion of the substrate material. The method generally involves washing and rinsing the part to remove contaminants or detergent residues from the part. Once washed and rinsed, the part is dried and cooled in preparation for the PVD step. When dry and cool, the part is loaded into a magnetron sputtering device, pumped down to high vacuum, and subjected to additional cleaning. Once fully cleaned, the parts are sputtered with a sacrificial alloy. After the sputtering step, the parts are subjected to a post-sputtering process to further increase the corrosion resistance of the parts. This is accomplished by applying a passivate solution to the sputtered parts. The sputter process mainly coats surfaces that are in the line-of-sight of the metal atoms in the plasma. As a result, portions of the part not in the line-of-sight will not be coated. For example, interior surfaces of a cylindrical part are not in the line-of-sight of the metal atoms in the plasma and thus are not coated during sputtering. These areas can be temporarily protected from corrosion by applying a rust inhibitor after the passivate step. The rust inhibitor is then allowed to dry.

As illustrated in FIG. 1, the part is first subjected to a pre-wash step 14. In particular, the part can be placed into a commercial washing machine, such as a Hobart style washing machine. The part is pre-washed by the Hobart machine with a detergent. One environmentally friendly, suitable detergent is commercially available as SIM Clean 101. Next, the part is washed in an ultrasonic bath of 5% SimClean 101 and water. In one embodiment, the part is preferably washed with water subjected to reverse osmosis (“RO”) filtration and heated to about 160 degrees Fahrenheit. The wash cycle of step 16 is preferably about 2 minutes in duration, although different durations may also produce acceptable results. As used herein, the term “wash” is defined broadly as cleansing using water, a solvent and/or another suitable fluid. Moreover, wash is defined to include cleansing by an ultrasonic bath.

Once the part is washed as detailed above, in steps 18 and 20 it is subjected to a rinse in a series of RO water baths to further remove any oils or contaminants, in addition to any remaining detergent residue from the pre-wash step 14-16. Heated RO water is added to the baths so as to create a cascading flow of RO water over the baffles of the bath tubs. The cascading flow of heated RO water thus carries away remaining oils, contaminants and detergent residues. The heated RO water can be approximately 160 degrees Fahrenheit. The part is subjected to each rinse bath for a period of approximately 10-15 seconds, although different durations may also produce acceptable results.

Instead of an aqueous wash, a solvent solution can be used in the washing step. Exemplary solvents suitable for washing the metal part(s) include petroleum based solvents, or other suitable solvents, which will become apparent to one of ordinary skill in the art in view of the present disclosure.

After the part is rinsed as described in steps 18 and 20, it is dried in step 26. A number of various drying apparatuses can be used to dry the part. For example, a series of air spouts arranged as an air knife can be used. In such an embodiment, high pressure air heated to 180 degrees Fahrenheit is directed onto the part for approximately one minute. This high velocity, concentrated air effectively sheets water off of the part. In addition, if the part is not completely dry using the air knife, it can be further blown off manually with a high pressure air hose. At this time, any interior portions of the part that are still wet can also be dried.

The dried part is then cooled in step 30 in preparation for the PVD step. It has been discovered that the temperature of the part during PVD is related to the luster, shine, or brightness of the end product. In particular, when the part is at approximately 65-75 degrees Fahrenheit, the sputtered part is lustrous, shiny, and bright. In contrast, when a part is sputtered at higher temperatures, for example over 150 degrees Fahrenheit, the part receives a dull or matte finish and darker in color. A number of different colors can be achieved, depending on the temperature, the gas environment in which parts are sputtered, and the type of passivate. For example, parts can be made into colors such as olive green, yellow, black, or even clear with respect to the substrate material.

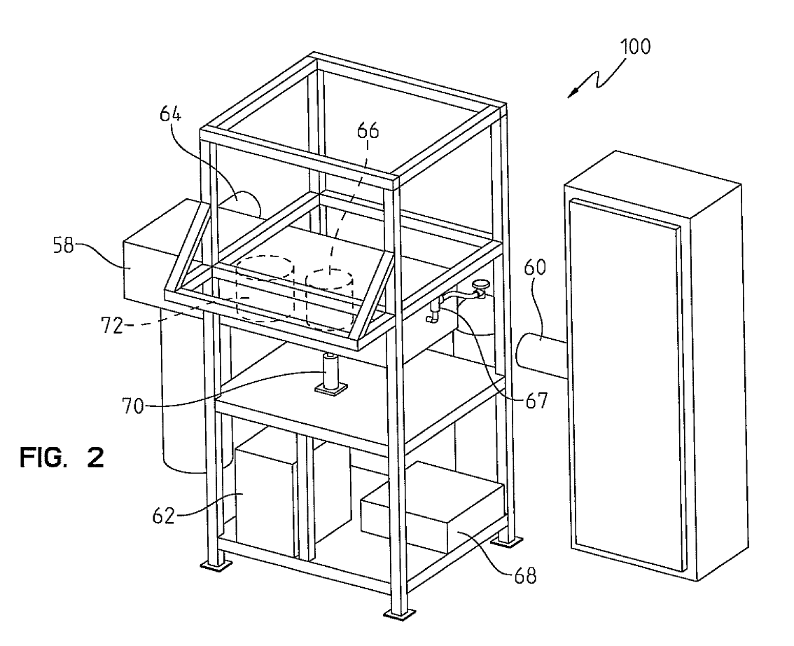

When the part is sufficiently cooled as described in step 30, it is ready for magnetron sputtering according to step 34. One exemplary magnetron sputtering device is depicted in FIG. 2 and is described in detail below. The part is placed onto a rack and subsequently loaded into vacuum chamber 58 by electric cylinder lift station 70 (FIG. 2). The vacuum chamber 58 is then sealed and evacuated in step 37 to approximately 6.times.10.sup.−5 Torr using a series of vacuum pumps, which are described in greater detail below.

After the chamber is properly evacuated, the part is ready to be ion glow discharge cleaned—or “glow cleaned”—as shown in step 35. Glow cleaning improves the adhesion of the coated material to the substrate. In particular, the glow clean process is accomplished by exposing the part to a ion plasma field within the vacuum chamber 58. This plasma field is formed by inputting a high voltage direct current into an in-chamber high voltage electrode. As the ions flow to the chamber walls, they bombard and microscopically etch the part, which is in their path, thereby removing remaining impurities from the part.

More specifically, to glow clean the part, the pallet containing the part and the part are electrically charged, thus creating a voltage drop between the part and the chamber. Argon gas (or any other similar inert gas) is then introduced into the chamber. The Argon gas is quickly ionized and is thus strongly attracted to the chamber walls. The charged part is thus bombarded by the Argon gas ions, which microscopically etch the part clean. The part can be subjected to the glow clean step 35 for approximately 5 seconds. Other ways of performing a glow clean step will become apparent to those of ordinary skill in the art in view of the present disclosure.

After the glow clean step 35, the part is sputtered in step 39. To sputter the part, combined electric and magnetic fields are created by the hollow cathode direct current magnetron sputtering source 66 (FIG. 2) to establish a large voltage differential (about 700 volts). The hollow cathode magnetron sputtering source 66 then excites the target alloy atoms and dislodges them from the target alloy 72. The Argon ions and the voltage differential then drives the target alloy atoms into a plasma field surrounding the part, thereby sputtering the part. The part is sputtered for approximately 150 seconds, although different durations may be used depending on the size of the magnetron sputtering device, the desired thickness of the sputter coating, power supply, the partial pressure of the Argon, the size of the target, and the distance between the part to be sputtered and the target. It should be noted that the part subjected to this embodiment of the present invention results in a light grey to black finish. Alternatively, other inert gases such as Nitrogen can be used to achieve a blue finish.

Once the part is sputtered in step 39, it is removed from the magnetron sputtering device and subjected to a post-sputtering treatment. Specifically, in step 36, a top coat is applied to the part. The top coat is preferably a passivate solution such as a trivalent chromate. A Trivalent chromate is commercially available under the trade name SurTec 667. The passivate solution can be combined with a sealer such as SurTec 551. Both the passivate and the sealer are commercially available through CST-SurTec. As used herein, the term “applied” is defined broadly, meaning to bring into contact with, e.g., to bath, dip, either fully or partially, or spray.

The part is then rinsed using RO water, as shown in step 40. Once rinsed, the part is bathed in a 10% solution of rust inhibitor in RO water, as shown in step 44. An exemplary rust inhibitor is commercially available as SealProof 6151, which is available through Innovative Chemical Solutions. The rust inhibitor provides corrosion resistance for sections of the part that are not sputtered, for example, interior portions. The part is then dried in step 48, either by a fan, an air knife, or other drying method that will become apparent to one of ordinary skill in the art in view of the present disclosure.

FIG. 2 illustrates the magnetron sputtering device 100 of one embodiment of the present invention. Sputtering device 100 includes sputtering vacuum chamber 58, a hollow cathode direct current magnetron sputtering source 66, a target material 72, an inert gas supply 67, and one or more evacuation pumps 60, 61, 62, and 64.

Vacuum chamber 58 can be configured in a wide variety of dimensions, depending on the size and quantity of the part(s) to be sputtered. In one embodiment of the present invention, the vacuum chamber 58 is 24 inches wide and 60 inches long and 17 inches high. The vacuum chamber 58 can also be provided with an integral welded tube frame. The vacuum chamber 58 further includes an electric or pneumatic cylinder lift station 70. Lift station 70 can further be outfitted with a rack to support the part(s) to be sputtered.

As further illustrated in FIG. 2, the vacuum chamber 58 houses a hollow cathode direct current magnetron sputtering source 66. For a vacuum chamber having the dimensions set forth above, sputtering source 66 can be approximately 14 inches in diameter by 12 inches high. Sputtering source 66 can be powered by a panel mounted 12 kilowatt direct current, alternating current, or radio frequency magnetron power supply 68. Of course, as will be apparent to a person of ordinary skill in the art in view of the present disclosure, the sputtering source can be enlarged or reduced in size depending on the size of the part or cluster of parts to be sputtered. Likewise, instead of a hollow cathode sputtering source, a planar magnetron could also be used.

As shown in FIG. 2, the vacuum chamber 58 further houses the target material 72. To impart corrosion resistance on the part(s) to be sputtered, a sacrificial metal or alloy target is preferably used. Exemplary sacrificial metals include Zinc or Aluminum. Exemplary sacrificial alloys include Zinc alloys such as Zinc and Aluminum alloys. One particular alloy includes approximately 98% Zinc and 2% Aluminum. Of course, Zinc-Aluminum alloys having larger percentages of Aluminum could alternatively be used. The target alloy 72 to be used with the vacuum chamber 58 and sputtering source 66 described above can be of a cylindrical shape. In particular, the dimensions of the cylindrical shape are approximately 12.75 inches in diameter by 12 inches high by 0.375 inches thick. Alternatively, for a planar magnetron, a target having dimensions of approximately 5 inches by 30 inches can be used.

The inert gas supply 67 provides inert gas, for example Argon, to be ionized in the vacuum chamber 58. The inert gas supply 67 preferably includes a storage cylinder in which the inert gas can be stored. An alternative gas that can be used is Nitrogen. Such a gas results in parts having a blue finish, as mentioned above.

Referring to FIG. 2, the sputtering device 100 includes one or more evacuation pumps, The evacuation pumps are configured to evacuate the vacuum chamber as detailed above. In particular, one embodiment of the magnetron sputtering device 100 includes a BOC Edwards 412J-014 mechanical pump and 900-615-MV15 blower 60, a Varian HS-16 diffusion pump 61, and a CT-10 Cryo-Pump 62 & 64. In combination, these pumps evacuate the vacuum chamber 58 to better than approximately 6.times.10.sup.−5 Torr.

In an alternative embodiment, a turbo pump could be used and/or a load lock system. A load lock configuration allows for the sputter chamber to remain constantly under vacuum, thereby allowing near constant sputtering of parts. That is, by maintaining a constantly evacuated vacuum chamber, a load lock system obviates the need to repeatedly evacuate the sputter chamber in between sputtering cycles.

A wide variety of magnetron sputtering variations will become apparent to one of ordinary skill in the art in view of the present disclosure. Such variations are thus considered to be within the scope of the present invention as defined by the claims. For Example, the use of a higher volume Magnetron sputtering device will be apparent to one of ordinary skill in the art in view of the present disclosure.

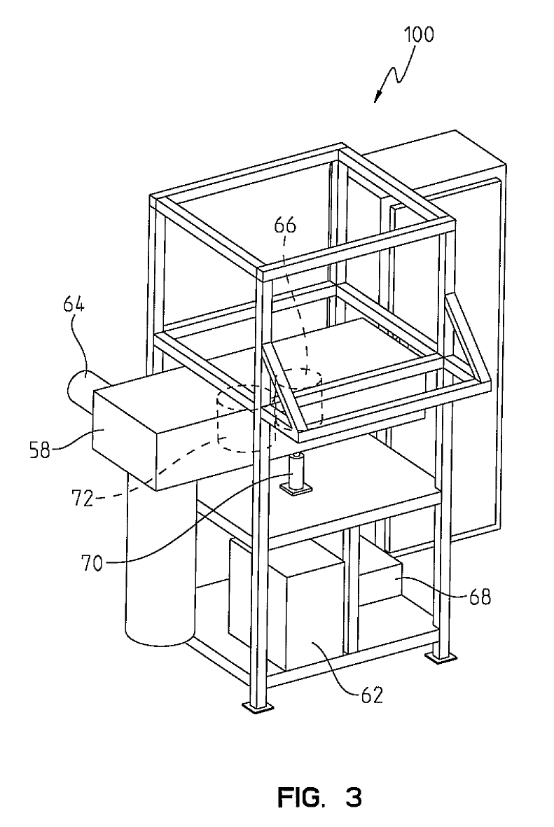

Referring now to FIG. 3, a sputter coated valve 200 is illustrated according to one aspect of the present invention. In particular, sputter coated valve 200 includes an interior portion 214 and an exterior portion 218. The exterior portion 218 has a hexagonal portion 222 for tightening or loosening the valve. The exterior portion 218 is provided with a corrosion resistant coating 230 using the process detailed above. One exemplary coating is a Zinc alloy as described in greater detail above. Coating 230 is relatively uniformly applied to exterior portion 218, including the hexagonal portion 222 and male thread 226. As a result of the uniformity and thickness of coating 230, the desired corrosion resistance is achieved without obstructing the mechanics of the valve. In addition, sputter coated valve 200 is provided with a rust preventative 234 covering both the interior portion 214 and the exterior portion 218. Valve 200 can be formed from a wide variety of materials such as mild steel or other alloys.

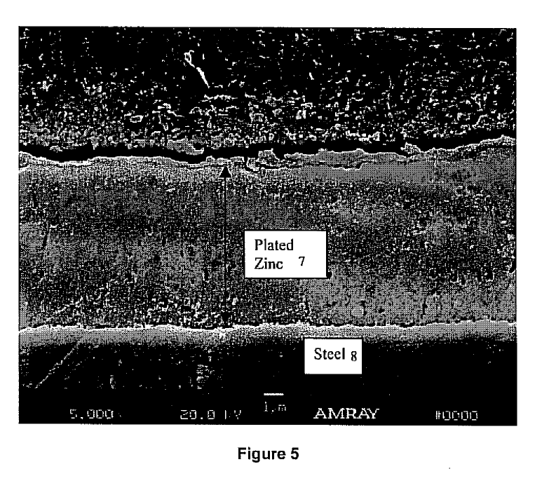

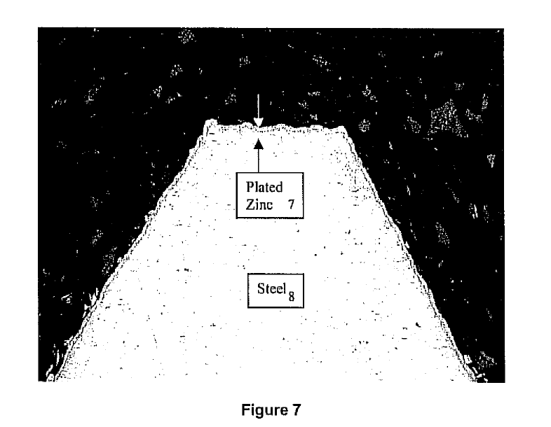

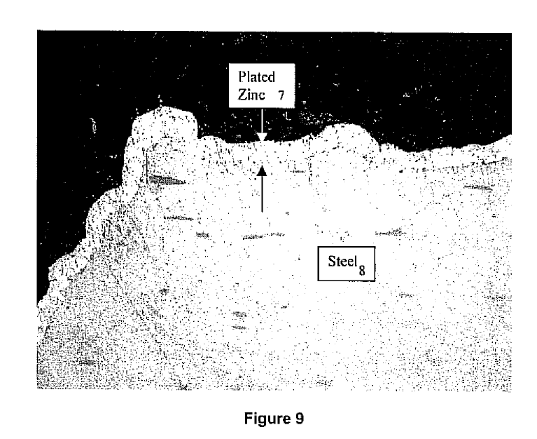

FIGS. 5, 7, and 9 illustrate steel substrates plated using conventional electroplating techniques. FIGS. 7 and 9 show the substantial thickness and non-uniform structure of conventionally plated zinc 7 relative to a steel substrate 8. FIG. 9, in particular, shows the substantial build-up of plated zinc 7 that occurs at the edges of a thread crest. Such build-up alters the dimensions of plated parts, thereby rendering them often unusable, as discussed above.

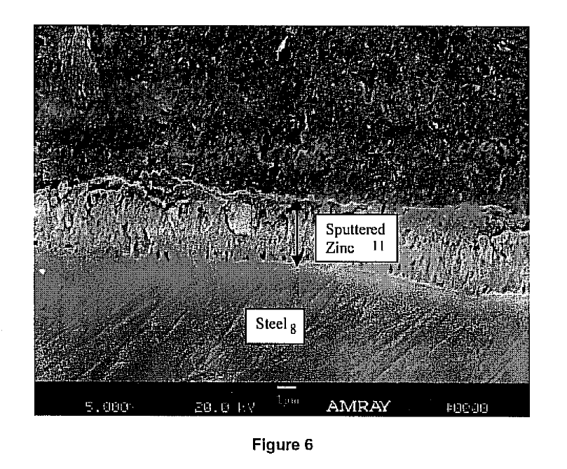

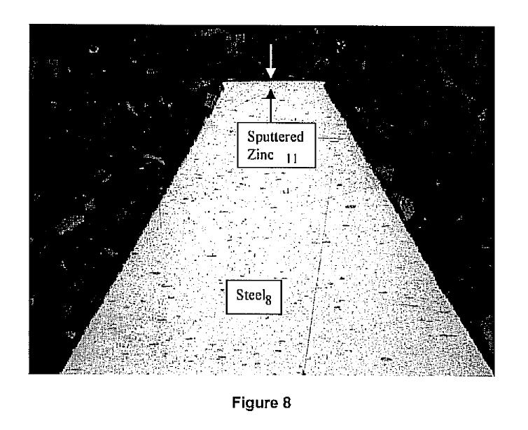

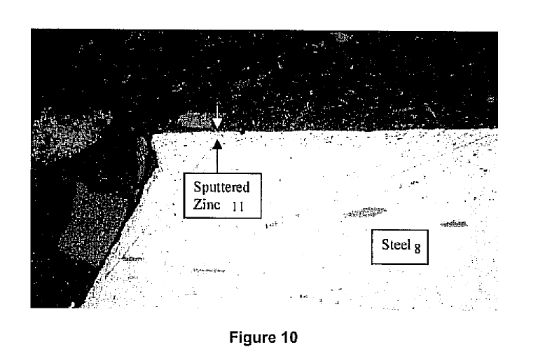

FIGS. 6, 8, and 10, illustrate a steel substrate sputter-coated with zinc using the process of FIG. 1. In particular, FIGS. 6, 8, and 10 illustrate the substantially thin and uniform structure of sputtered zinc 11 relative to steel substrate 8. Additionally, FIGS. 6, 8, and 10 lack the undesirable build-up seen in conventionally plated steel parts.

It is therefore intended that the foregoing detailed description be regarded as illustrative rather than limiting, and that it be understood that it is the following claims, including all equivalents, that are intended to define the spirit and scope of this invention.

What is claimed is:

1. A process for coating a metal part, the process comprising the steps of:
a) washing the metal part;
b) rinsing the metal part;
c) inserting the metal part in a magnetron sputtering device; and
d) sputtering the metal part with a uniform layer of a sacrificial target material.

2. The process of claim 1, wherein the washing step a) comprises washing the metal part with heated water; and the rinsing step b) comprises rinsing the metal part using heated, filtered water.

3. The process of claim 2, further comprising the steps of filtering the water in the rinsing step b) by reverse osmosis, and heating the water in the washing step and the rinsing step to a temperature between 100 degrees and 200 degrees Fahrenheit.

4. The process of claim 1, further comprising the steps of
e) bathing the metal part in a passivate solution; and
f) rinsing the metal part in water after bathing step e).

5. The process of claim 4, wherein the inserting step c) further comprises the step of:
bombarding the metal part with ions, thereby etching the metal part and removing contaminants from the metal part.

6. The process of claim 5, further comprising the step of cooling the metal part before the inserting step c).

7. The process of claim 5, further comprising the step of: g) coating the metal part with a rust inhibitor.

8. The process of claim 7, wherein the sacrificial target material comprises Aluminum.

9. The process of claim 8, wherein the sacrificial target material comprises Zinc.

10. The process of claim 1, wherein the sacrificial target material comprises Zinc and Aluminum.

11. The process of claim 1, wherein the metal part is comprised of a mild steel and the sacrificial target material is comprised of Zinc.

12. A metal part comprising a surface treated in accordance with the process of claim 11.

13. The metal part of claim 12, wherein the metal part is a cylindrical valve body.

14. A process for coating a metal part, the process comprising the steps of:
a) washing the metal part with water having a temperature greater than 100 degrees Fahrenheit and a detergent;
b) rinsing the metal part with filtered water having a temperature greater than 120 degrees Fahrenheit in a first cascade bath;
c) drying the metal part with a stream of heated gas;
d) cooling the metal part to a temperature between 60 and 70 degrees Fahrenheit;
e) inserting the metal part in a magnetron sputtering device;
f) ionizing glow cleaning the metal part;
g) sputtering the metal part with a first layer of a target material comprising Zinc;
h) applying a trivalent chromate to the metal part;
i) coating the metal part with a sealer; and
j) coating the metal part with a rust inhibitor.

15. A metal part comprising a surface treated in accordance with the process of claim 14.

16. The metal part of claim 15, wherein the metal part is formed from mild steel.
